(19) United States
(12) Patent Application Publication
(10) Pub. No.: US 2018/0156961 A1
(43) Pub. Date: Jun. 7, 2018

(54) ILLUMINATION DEVICE AND DISPLAY DEVICE

(71) Applicant: Japan Display Inc., Minato-ku (JP)

(72) Inventor: Hirohisa MIKI, Tokyo (JP)

(73) Assignee: Japan Display Inc., Minato-ku (JP)

(21) Appl. No.: 15/813,821

(22) Filed: Nov. 15, 2017

(30) Foreign Application Priority Data
Dec. 5, 2016 (JP) 2016-235851

(51) Int. Cl. F21V 8/00; G02F 1/1335; G02F 1/1333; G02F 1/1343; H01L 25/075; H01L 33/62; H01L 33/50; H01L 33/56; H01L 33/58

(52) U.S. Cl. CPC G02B 6/0028; G02F 1/1337; G02B 6/0091; G02B 6/0055; G02B 6/009; G02B 6/0088; G02F 1/133514; G02F 1/133528; G02F 1/133345; G02F 1/134309; G02F 1/13439; G02F 1/133512; H01L 25/0753; H01L 33/62; H01L 33/502; H01L 33/505; H01L 33/507; H01L 33/56; H01L 33/58; G02F 2201/121; G02F 2201/123; G02B 6/0026

(57) ABSTRACT

According to one embodiment, an illumination device includes a light emitting chip including a main surface and a side surface and emitting light, a sealing member including a scattering member and sealing the main surface and the side surface, and a wavelength converting member converting a wavelength of the light emitted from the light emitting chip.

### CROSS-REFERENCE TO RELATED APPLICATIONS

This application is based upon and claims the benefit of priority from Japanese Patent Application No. 2016-235851, filed Dec. 5, 2016, the entire contents of which are incorporated herein by reference.

### FIELD

Embodiments described herein relate generally to an illumination device and a display device.

### BACKGROUND

An illumination device comprising a light source such as a light-emitting diode (LED) and a wavelength converting member including a phosphor in combination has been proposed as an illumination device applied to a flat-panel display device such as a liquid crystal display device. For example, a linear light emitting device for emitting a linear light beam by introducing light from an end side of a linear light guide comprising light diffusing and reflecting portions formed at regular intervals has been proposed. In addition, a light emitting device in which light emitting portions comprising semiconductor light emitting elements and wavelength converting layers are aligned and light guide members provided between adjacent light emitting portions partially cover the wavelength converting layers has been proposed as the other example.

The light (excited light) emitted from the light source is backscattered by the wavelength converting member or the light having its wavelength converted by the wavelength converting member returns to the light source side, and the light may be lost. For this reason, the efficiency of use of light is required to be improved.

### BRIEF DESCRIPTION OF THE DRAWINGS

FIG. 1 is a perspective view showing a display device DSP according to one of the embodiments.

FIG. 2 is a cross-sectional view showing pixels PX1 to PX3 in a display area of the display device DSP shown in FIG. 1.

FIG. 3 is a plan view showing a configuration of the illumination device IL according to the present embodiment.

FIG. 4 is an exploded perspective view showing a light source unit 30 and a sub-light guide 40 shown in FIG. 3.

FIG. 5 is a cross-sectional view showing a configuration example of the illumination device IL shown in FIG. 3.

FIG. 6 is a cross-sectional view showing another configuration example of the illumination device IL shown in FIG. 3.

FIG. 7 is a cross-sectional view showing the other configuration example of the illumination device IL shown in FIG. 3.

FIG. 8 is a cross-sectional view showing the other configuration example of the illumination device IL shown in FIG. 3.

FIG. 9 is a plan view showing a configuration of an illumination device IL according to another embodiment.

FIG. 10 is a graph for explanation of a directivity of a light beam emitted from the sub-light guide 40 of the illumination device IL shown in FIG. 9.

FIG. 11 is a plan view showing a configuration of an illumination device IL according to the other embodiment.

### DETAILED DESCRIPTION

In general, according to one embodiment, an illumination device includes: a light emitting chip including a main surface and a side surface and emitting light; a sealing member including a scattering member and sealing the main surface and the side surface; and a wavelength converting member converting a wavelength of the light emitted from the light emitting chip.

According to another embodiment, a display device includes: an illumination device; and a display panel illuminated by the illumination device, the illumination device comprising: a light emitting chip including a main surface and a side surface and emitting light; a sealing member including a scattering member and sealing the main surface and the side surface; and a wavelength converting member converting a wavelength of the light emitted from the light emitting chip.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, the same elements as those described in connection with preceding drawings are denoted by like reference numbers, and detailed description thereof is omitted unless necessary.

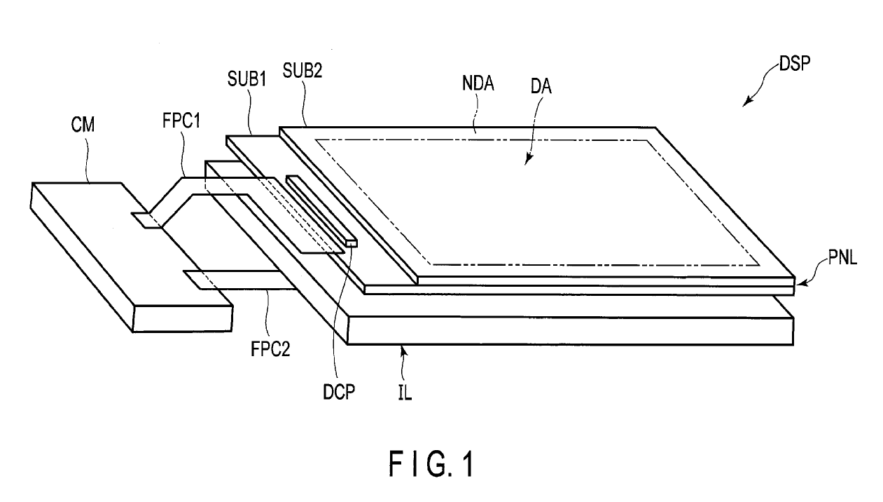

FIG. 1 is a perspective view showing a display device DSP according to one of the embodiments.

The display device DSP comprises an illumination device IL and a display panel PNL illuminated by the illumination device IL. The display panel PNL is, for example, a liquid crystal panel and includes a first substrate SUB1, a second substrate SUB2 opposed to the first substrate SUB1, and a liquid crystal layer (not shown) held between the first substrate SUB1 and the second substrate SUB2. The display panel PNL includes a display area DA on which an image is displayed and a frame-shaped non-display area NDA located in the surrounding of the display area DA. The illumination device IL is disposed on a side opposed to the first substrate SUB1 of the display panel PNL. Details of the illumination device IL will be explained later.

The driver IC chip DCP is mounted on the first substrate SUB1 of the display panel PNL. The driver IC chip DCP incorporates a drive circuit necessary to drive the display panel PNL and the like. A flexible printed circuit FPC1 connects the display panel PNL with the control module CM. A flexible printed circuit FPC2 connects the illumination device IL with the control module CM. The control module CM outputs a signal necessary to drive the display panel PNL via the flexible printed circuit FPC1 and also outputs a signal necessary to drive the illumination device IL via the flexible printed circuit FPC2.

The display device DSP of the configuration shown in the figures is, for example, a transmissive display device comprising a transmissive display function of displaying an image by causing the light incident on the display panel PNL from the illumination device IL to be transmitted selectively. The display device DSP of the present embodiments is not limited to a transmissive display device. For example, the display device DSP may be a reflective display device which displays an image by causing light incident from the illumination device IL to the display panel PNL to be transmitted selectively or a transflective display device comprising both of the transmissive display function and the reflective display function. If the display device DSP is a reflective display device, the illumination device IL may be disposed on a side opposed to the second substrate SUB2 of the display panel PNL.

The display panel PNL is not limited to a liquid crystal panel but may be a display panel comprising an electrophoretic element, a display panel employing micro-electromechanical systems, a display panel employing electrochromism, or the like.

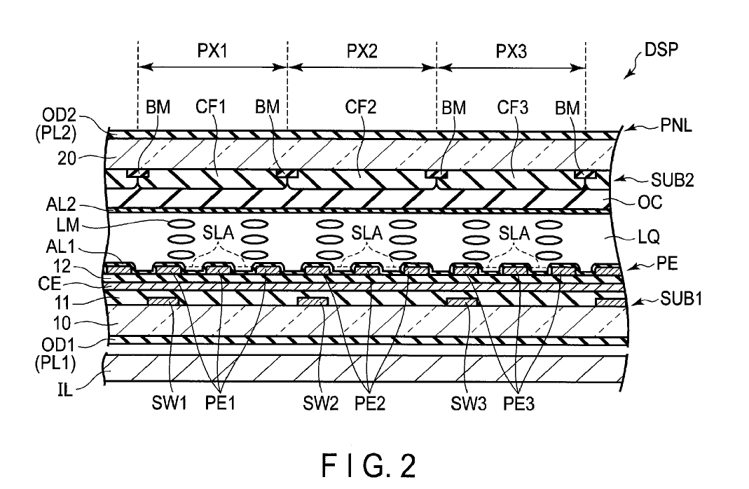

FIG. 2 is a cross-sectional view showing pixels PX1 to PX3 in a display area of the display device DSP shown in FIG. 1. A liquid crystal display device of a display mode using the lateral electric field is shown in FIG. 2 as an example of the display device DSP. However, the display mode applicable to the display device DSP of the present embodiments is not limited to the example illustrated but may be a display mode using the longitudinal electric field.

In the present embodiments, a direction from the first substrate SUB1 to the second substrate SUB2 is called an upward direction (or, more simply, upwardly) and a direction from the second substrate SUB2 to the first substrate SUB1 is called a downward direction (or, more simply, downwardly). A view from the second substrate SUB2 to the first substrate SUB1 is called a planar view.

The display panel PNL comprises a liquid crystal layer LC between the first substrate SUB1 and the second substrate SUB2. In addition, the display panel PNL comprises a first optical element OD1 on an outer surface of the first substrate SUB1 and a second optical element OD2 on an outer surface of the second substrate SUB2. Each of the optical elements OD1 and OD2 comprises a polarizer. The second optical element OD2 comprises a second polarizer PL2. An absorption axis of the first polarizer PL1 and an absorption axis of the second polarizer PL2 are, for example, orthogonal to each other.

The first substrate SUB1 includes a first insulating substrate 10, switching elements SW1 to SW3, a first insulating film 11, a common electrode CE, a second insulating film 12, pixel electrodes PE1 to PE3, a first alignment film AL1 and the like. The first insulating substrate 10 is a glass substrate, a resin substrate or the like. The switching elements SW1 to SW3 are disposed on the first insulating substrate 10. The first insulating film 11 is disposed on the first insulating substrate 10 and the switching elements SW1 to SW3. The common electrode CE is disposed on the first insulating film 11. The second insulating film 12 is disposed on the common electrode CE. The pixel electrodes PE1 to PE3 are disposed on the second insulating film 12 and opposed to the common electrode CE via the second insulating film 12. Slits SLA are formed in each of the pixel electrodes PE1 to PE3. The pixel electrodes PE1 to PE3 are disposed in areas corresponding to the pixels PX1 to PX3 and electrically connected to the switching elements SW1 to SW3, respectively. The common electrode CE and the pixel electrodes PE1 to PE3 are formed of, for example, a transparent conductive material such as indium-tin-oxide (ITO) or indium-zinc-oxide (IZO). The first alignment film AL1 covers the second insulating film 12 and the pixel electrodes PE1 to PE3.

The second substrate SUB2 includes a second insulating substrate 20, a light-shielding layer BM, color filters CF1 to CF3, an overcoat layer OC, a second alignment film AL2, and the like. The second insulating substrate 20 is a glass substrate, a resin substrate or the like. The light-shielding layer BM and the color filters CF1 to CF3 are disposed on a side of the insulating substrate 20 which is opposed to the first substrate SUB1. The color filters CF1 to CF3 are disposed in areas corresponding to the pixels PX1 to PX3, respectively. The color filters CF1 to CF3 are, for example, a red color filter, a green color filter, and a blue color filter but may be the other color filters or a white color layer or transparent layer. The overcoat layer OC covers the color filters CF1 to CF3. The second alignment film AL2 covers the overcoat layer OC. The first alignment film AL1 and the second alignment film AL2 indicate, for example, a horizontal alignment property in which liquid crystal molecules LM included in a liquid crystal layer LC are aligned in a direction approximately parallel to the main surface of the substrate. The liquid crystal layer LC is disposed between the first alignment film AL1 and the second alignment film AL2.

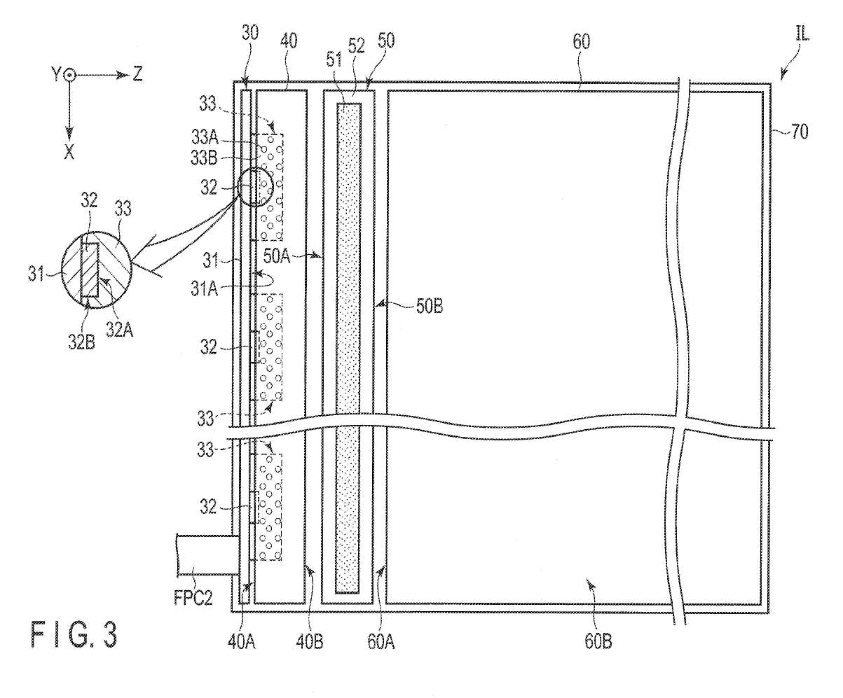

Next, a structure of the illumination device IL will be explained with reference to the drawings. In the drawings, a first direction X, a second direction Y and a third direction Z are orthogonal to each other but may intersect at an angle other than 90 degrees. FIG. 3 is a plan view showing a configuration of the illumination device IL according to the present embodiment.

The illumination device IL comprises a light source unit 30, a sub-light guide 40, a wavelength converting member 50, a main light guide 60, and a reflecting member 70. The light source unit 30, the sub-light guide 40, the wavelength converting member 50, and the main light guide 60 are arranged in this order in the third direction Z.

The light source unit 30 extends in the first direction X. The light source unit 30 comprises a printed circuit board 31, light emitting chips 32, and sealing members 33.

The printed circuit board 31 extends in the first direction X and is connected with the control module CM shown in FIG. 1 via the flexible printed circuit FPC2. The printed circuit board 31 has a surface 31A opposed to the sub-light guide 40.

The light emitting chip 32 is a light-emitting diode which emits light and has a main surface 32A and a side surface 32B as shown in a partially expanded figure. The light emitting chip 32 employed in the present embodiment is a light-emitting diode which is not equipped intentionally with a cup-shaped reflector generally disposed to surround a sealing resin containing a phosphor, and is directly mounted on the printed board. The light emitting chip 32 is a light-emitting diode which emits light from the main surface 32A and is designed in a top view type or a side view type but light may be emitted from both of the main surface 32A and the side view 32B. The light emitting chips 32 are arranged in the first direction X to be spaced apart and mounted on the surface 31A.

The sealing member 33 includes scattering members 33A and seals the main surface 32A and the side surface 32B of the light emitting chip 32 as shown in a partially expanded figure. More specifically, the sealing member 33 surrounds the entire body of the light emitting chip 32 protruding from the printed circuit board 31 and is in contact with the surface 31A of the printed surface board 31. The sealing member 33 is formed of, for example, a transparent resin 33B in which the scattering members 33A are dispersed. A refractive index nA of the scattering members 33A is different from a refractive index nB of the transparent resin 33B and, for example, the refractive index nA is larger than the refractive index nB. The scattering members 33A are, for example, beads formed of glass, resin or ceramics. The scattering members 33A have, for example, an average particle size of approximately 5 μm and the refractive index nA of approximately 1.5, and their volume percentage of the total volume of the sealing member 33 is approximately 5%. In contrast, the transparent resin 33B may be formed to have the refractive index nB of approximately 1.4.

The sub-light guide 40 extends in the first direction X, surrounds each of the sealing members 33 on the light source unit 30, and is located between the sealing members 33 and the wavelength converting member 50 in the third direction Z. In other words, the sub-light guide 40 includes recess portions on a side opposed to the light source unit 30, and the sealing members 33 protruding from the printed circuit board 31 are fit in the recess portions. Each of the faces forming the recess portions corresponds to the incidence surface on which the light emitted from the light source unit 30 is made incident. The structure of the recess portions will be explained below in detail. The sub-light guide 40 has an end surface 40A opposed to the surface 31A of the printed circuit board 31 and an end surface 40B opposed to the wavelength converting member 50. The end surface 40B corresponds to an incidence surface (first surface) on which the light is emitted from the sub-light guide 40 to the wavelength converting member 50. The end surfaces 40A and 40B may be flat surfaces parallel to the X-Y plane defined by the first direction X and the second direction Y or may be uneven surfaces as explained below. The sub-light guide 40 is formed of, for example, glass or resin and is transparent. The refractive index of the sub-light guide 40 is desirably approximately equal to the refractive index of the sealing members 33.

The wavelength converting member 50 extends in the first direction X and is located between the sub-light guide 40 and the main light guide 60 in the third direction Z. The wavelength converting member 50 has an end surface 50A opposed to the sub-light guide 40 and an end surface 50B opposed to the main light guide 60. The end surface 50A corresponds to an incidence surface (second surface) on which the light emitted from the light emitting chip 32 is made incident. The end surface 50B corresponds to an emission surface on which the light is emitted from the wavelength converting member 50 to the main light guide 60. The end surfaces 50A and 50B may be flat surfaces parallel to the X-Y plane or may be uneven surfaces as explained below.

The wavelength converting member 50 comprises, for example, an emitting material 51 which generates photoluminescence. The emitting material 51 absorbs light of a specific wavelength and emits light of a longer wavelength than the wavelength of the absorbed light. Examples of the emitting material 51 are an emitting material which absorbs blue light and ultraviolet light and emits yellow light, an emitting material which emits green light, an emitting material which emits red light, and the like. The wavelength converting member 50 may comprise not only one type of the emitting material 51 but two or more types of the emitting materials 51.

In the example illustrated, the emitting material 51 is formed of quantum dots. The quantum dots are, for example, crystal of a semiconductor having outer dimensions in a range from several nanometers to several tens of nanometers. The quantum dots of the present embodiment are formed of, for example, II- to VI-group semiconductors or III- to V-group semiconductors having a crystal structure in a wurtzite type or a sphalerite type. The quantum dots are formed to have, for example, a core-shell structure. The core is located in the center of the quantum dot and is formed of, for example, cadmium selenide (CdSe), cadmium telluride (CdTe), indium phosphide (InP) or the like. The shell covers the surrounding of the core to stabilize the core physically and chemically. The surrounding of the shell is often modified by organic molecules. The shell is formed of, for example, zinc sulfide (ZnS), cadmium sulfide (CdS) or the like. The quantum dot has an emission wavelength selectivity in accordance with the type and size of the semiconductor of the core. The quantum dot having a desirable emission wavelength can be thereby formed.

For example, the emitting material 51 is sealed in an airtight member 52 in a state of being dispersed in, for example, an appropriate binder resin or solvent. The airtight member 52 is, for example, a tubular body extending in the first direction X but is not particularly limited to this. The airtight member 52 is formed of, for example, glass or resin. If a material which can easily be degraded by oxygen or moisture as the emitting material 51, the airtight member 52 is desirably formed of a material having a high airtightness and low moisture permeability and is desirable formed of, for example, a glass tube.

The main light guide 60 is shaped in a flat plate which is rectangular in the X-Z plane defined by the first direction X and the third direction Z, and is opposed to the wavelength converting member 50 in the third direction Z. The main light guide 60 has an end surface 60A opposed to the wavelength converting member and a main surface 60B opposed to the first substrate SUB1 shown in FIG. 1. The end surface 60A corresponds to an incidence surface (third surface) on which the light emitted from the wavelength converting member 50 is made incident. The main surface 60B corresponds to an emission surface on which the light is emitted from the main light guide 60 to the display panel PNL. The end surface 60A may be a flat surface parallel to the X-Y plane or may be an uneven surface as explained below. Any one of the above-explained uneven surfaces may be formed of a lens array in which lenses are arranged, a prism array in which prisms are arranged or a slit array in which slits are arranged.

The reflecting member 70 is located under the above-explained optical members and is disposed under not only the main light guide 60, but also the light source unit 30, the sub-light guide 40 and the wavelength converting member 50 in the example illustrated. The reflecting member 70 is formed integrally in the example illustrated, and is not limited to this example but may be composed of members opposed to the respective optical members. Alternately, the reflecting member 70 may be formed in a sheet shape but may be a thin film formed on the lower surface of each of the optical members. The reflecting member 70 is formed of a material having a high light reflectance, for example, a dielectric multi-layer film or a metal material of aluminum or the like.

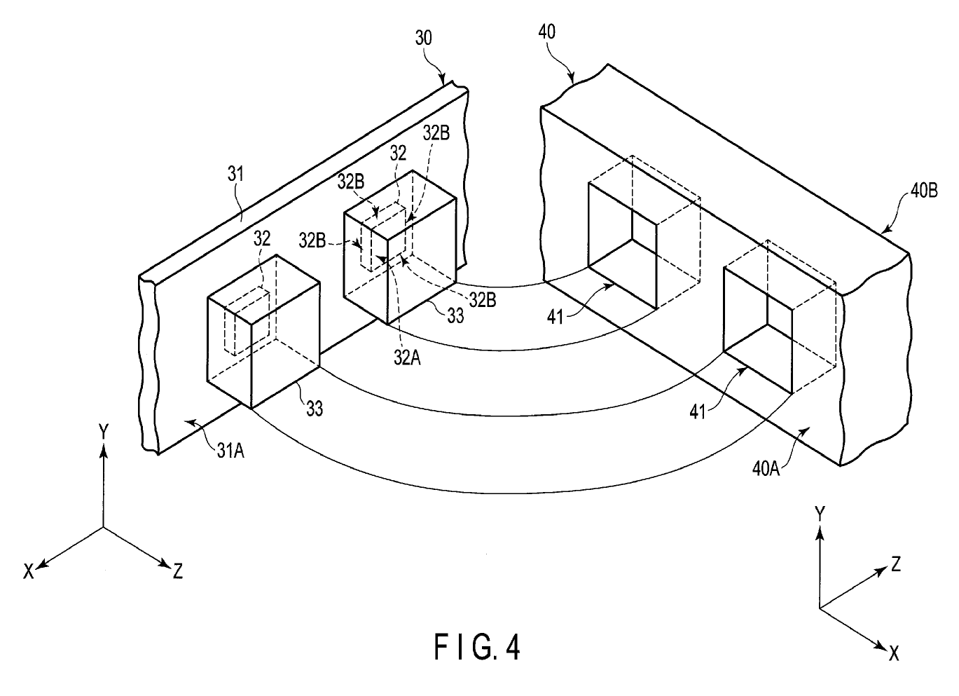

FIG. 4 is an exploded perspective view showing a light source unit 30 and a sub-light guide 40 shown in FIG. 3.

In the light source unit 30, the light emitting chip 32 is formed in an approximately rectangular parallelepiped shape and the main surface 32A is parallel to the X-Y plane. The sealing member 33 is formed in an approximately rectangular parallelepiped shape and covers not only the main surface 32A of the light emitting chip 32, but all of the side surfaces 32B. The light emitting chips 32 adjacent in the first direction X are sealed by sealing members 33, respectively. The sealing members 33 are arranged in the first direction X to be spaced apart.

In the sub-light guide 40, the recess portion 41 is formed in an approximately rectangular parallelepiped shape, similarly to the outer shape of the sealing members 33. The recess portion 41 is recessed from the end surface 40A toward the end surface 40B, but does not penetrate to the end surface 40B. The recess portions 41 are arranged in the first direction X to be spaced apart. When each of the sealing members 33 is fitted in the recess portion 41, an air layer may be interposed between the sealing member 33 and the sub-light guide 40 or the sealing member 33 may be in close contact with the sub-light guide 40.

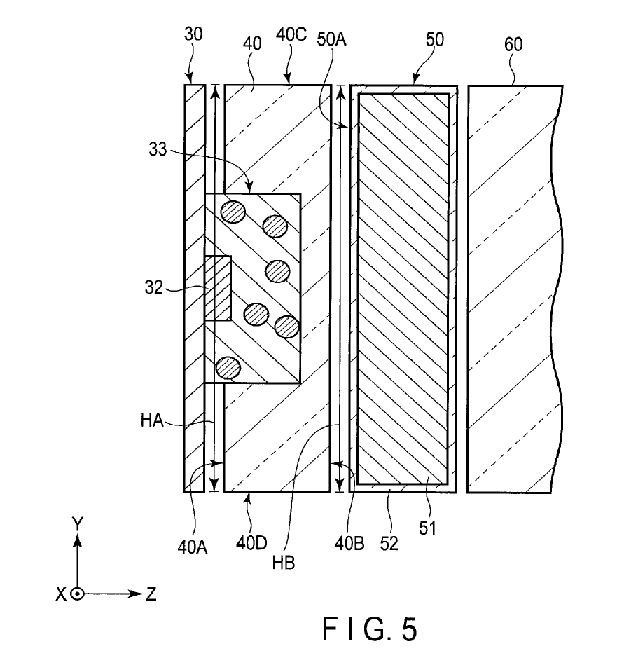

FIG. 5 is a cross-sectional view showing a configuration example of the illumination device IL shown in FIG. 3. The illustrated cross-section corresponds to a cross-section in the Y-Z plane defined by the second direction Y and the third direction Z. The only main portions of the illumination device IL are partially shown in the figure.

The sub-light guide 40 surrounding the sealing member 33 has a rectangular cross-section in the Y-Z plane and a height HA on the end surface 40A side in the second direction Y is equal to a height HB on the end surface 40B side in the second direction Y. In addition, each of an upper surface 40C and a lower surface 40D of the sub-light guide 40 is parallel to the X-Z plane. An end surface 50A of the wavelength converting member 50 is opposed to an end surface 40B.

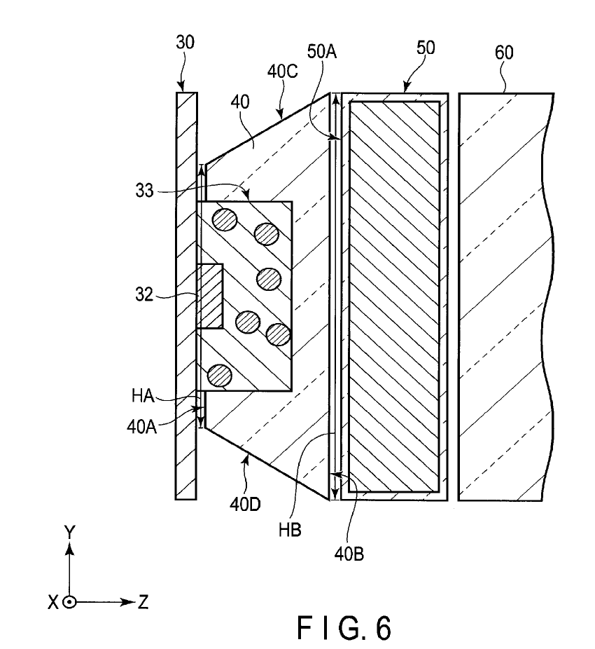

FIG. 6 is a cross-sectional view showing another configuration example of the illumination device IL shown in FIG. 3.

The illumination device IL shown in FIG. 6 is different from the configuration example of the illumination device IL shown in FIG. 5 with respect to a feature that the sub-light guide 40 has a trapezoidal cross-section in the Y-Z plane. In addition, each of an upper surface 40C and a lower surface 40D of the sub-light guide 40 is a surface inclined to the X-Z plane.

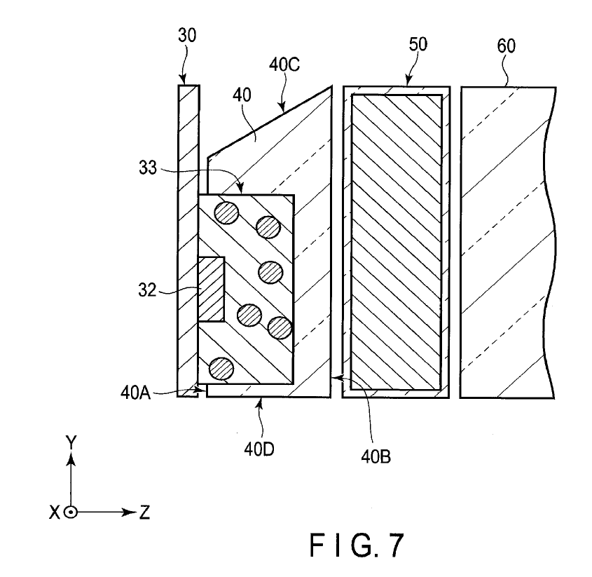

FIG. 7 is a cross-sectional view showing the other configuration example of the illumination device IL shown in FIG. 3.

The illumination device IL shown in FIG. 7 is different from the configuration example of the illumination device IL shown in FIG. 6 with respect to a feature that the lower surface 40D of the sub-light guide 40 is parallel to the X-Z plane. The illumination device IL shown in FIG. 7 is the same as the configuration example shown in FIG. 6 with respect to a feature that the upper surface 40C is a surface inclined to the X-Z plane.

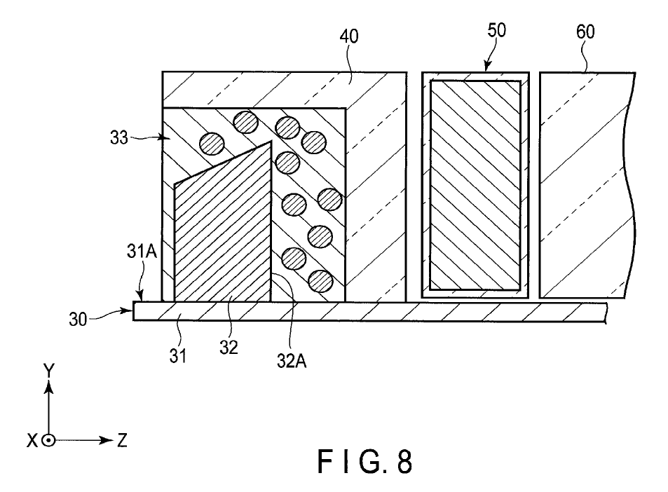

FIG. 8 is a cross-sectional view showing the other configuration example of the illumination device IL shown in FIG. 3.

The illumination device IL shown in FIG. 8 is different from the configuration example of the illumination device IL shown in FIG. 7 with respect to a feature that the light emitting chip 32 is a side view type light-emitting diode. The main surface 32A on which light is emitted is approximately parallel to the surface 31A of the printed circuit board 31 in the top view type while the main surface 32A on which light is emitted is approximately orthogonal to the printed circuit board 31 in the side view type. In the example illustrated, the surface 31A of the printed circuit board 31 is approximately parallel to the X-Z plane while the main surface 32A is approximately parallel to the X-Y plane.

The sealing member 33 seals the light emitting chip 32 and covers the main surface 32A. The sub-light guide 40 surrounds the sealing members 33.

In any one of the above-explained configuration examples of the illumination device IL, the wavelength converting member 50 has an approximately rectangular cross-section in the Y-Z plane, but the shape of the cross-section is not limited to this and may be a circular shape or the other polygonal shape. Next, operations of the illumination device IL according to the present embodiment will be explained with reference to FIG. 3.

In the light source unit 30, the light emitting chips 32 emit light from the main surface 32A to the wavelength converting member 50. The light emitted from the main surface 32A is made incident on the sealing members 33. At this time, a light beam traveling to the sides of the light emitting chips 32 and a light beam traveling to the printed circuit board 31 side, of the emitted light, are made incident on the sealing members 33 without being lost as stray light since the sealing members 33 surround the entire bodies of the light emitting chips 32.

The light incident on the sealing members 33 is scattered by the scattering members 33A at the sealing members 33 and is made incident on the sub-light guide 40. At this time, the light emitted from the sealing members 33 is made incident on the sub-light guide 40 without being lost in the interface between the sealing members 33 and the sub-light guide 40 since the sub-light guide 40 has an approximately equivalent refractive index to the sealing members 33. In addition, the light traveling to the printed circuit board 31 side, of the light emitted from the sealing members 33, is made incident on the sub-light guide 40 without being lost as stray light or the like since the sub-light guide 40 surrounds the approximately entire body of the sealing members 33.

The light incident on the sub-light guide 40 is emitted from the end surface 40B and made incident on the wavelength converting member 50. The light incident from the end surface 50A is partially absorbed into the emitting material 51. In the wavelength converting member 50, light that is not absorbed into the emitting material 51 is emitted from the wavelength converting member 50 and made incident on the main light guide 60. The emitting material 51 emits light of a longer wavelength than the wavelength of the absorbed light. At this time, the emitting material 51 emits light in approximately all directions. For example, light having its wavelength converted by the emitting material 51 is emitted from the end surface 50B of the wavelength converting member 50 and made incident on the end surface 60A of the main light guide 60. In contrast, part of the converted light becomes return light traveling from the wavelength converting member 50 to the light source unit 30 via the sub-light guide 40.

The converted light incident on the main light guide 60 is emitted from the main surface 60B and illuminates the display panel PNL. In contrast, the return light is made incident on the sub-light guide 40, part of the light is reflected on the sub-light guide 40 and emitted again to the wavelength converting member 50, and the other part of the light is made incident on the sub-light guide 40, then incident on the sealing members 33, scattered by the scattering member 33A, and emitted again to the wavelength converting member 50. For this reason, the return light can also be used as illumination light without being lost.

The light beam emitted from the light source unit 30, the light beam having its wavelength converted by the wavelength converting member 50, and the like propagate in the X-Z plane, but the light traveling to the lower surface side of each optical member is reflected by the reflecting member 70 and is made incident again on each optical member without being lost.

In the illumination device IL, the illumination light emitted from the main surface 60B is the converted light emitted mainly from the wavelength converting member 50. The illumination light may be a mixture of the converted light with the light which is not absorbed into the emitting material 51 (i.e., light having its wavelength not converted), of the light emitted from the light source unit 30.

In a configuration example, the light emitting chip 32 is a light-emitting diode which emits light (excited light) of an ultraviolet wavelength, and the wavelength converting member 50 contains the emitting material 51 which emits blue light, green light, and red light. In this configuration example, the blue emitting material 51 absorbs the excited light and emits blue color, the green emitting material 51 absorbs the excited light and emits green color, and the red emitting material 51 absorbs the excited light and emits red color, in the wavelength converting member 50. The illumination device IL can therefore emit white light obtained by mixing blue light, green light, and red light, as the illumination light.

In the other configuration example, the light emitting chip 32 is a light-emitting diode which emits light (excited light) of a blue wavelength, and the wavelength converting member 50 contains the emitting material 51 which emits yellow light. In this configuration example, the emitting material 51 absorbs the excitation light and emits yellow light at the wavelength converting member 50. The illumination device IL can therefore emit white light obtained by mixing the yellow light which is the converted light and the blue light which is the unconverted light, as the illumination light.

The illumination device IL emits white light as the illumination light in the above explanations, but the illumination light is not limited to white light and light of the other color may be emitted as the illumination light.

According to the present embodiment, the light emitting chip 32 is a light-emitting diode which is not equipped with a reflector, and its main surface (or light emitting surface) and side surface are sealed by the sealing members 33 including the scattering members 33A. For this reason, loss of the light emitted from the light emitting chip 32 which results from undesired reflection on the wall surfaces of the package and the like, the surface of the metal member, the interface of adhesives and the like different in refractive index can be suppressed as compared with the light-emitting diode in which the light emitting surface is surrounded by the package. In addition, the directivity of the light emitted from the light emitting chip 32 is controlled by the sealing members 33 including the scattering members 33A and emitted to the wavelength converting member 50. Loss of the return light of the light converted by the wavelength converting member 50, which results from the undesired reflection at the light source unit 30, can be suppressed. In addition, the light beam emitted from the light emitting chip 32 and the return light beam from the wavelength converting member 50 are scattered by the scattering members 33A in the sealing members 33 and emitted again to the wavelength converting member 50. The efficiency of use of light in the light source unit 30 can be therefore improved.

In addition, the directivity of the light scatted by the sealing members 33 can be improved by providing the sub-light guide 40 surrounding the sealing members 33, and the efficiency of use of light can be further improved. In addition, since the sub-light guide 40 is located between the light source unit 30 and the wavelength converting member 50, heat from the light source unit 30 can hardly be transmitted to the emitting material 51 as compared with a structure that the light emitting chip 32 is adjacent to the wavelength converting member 50. For this reason, degradation caused by heat from the emitting material 51 can be suppressed.

In addition, since the display panel PNL is illuminated by the illumination device IL configured as explained above, luminance of the display device DSP can be improved.

In addition, the wavelength converting member 50 comprises the emitting material 51 formed of the quantum dots. The emitting material 51 has a sharp peak in the emission spectrum as compared with a generally used phosphor and the like and can extend the color gamut.

Next, the other embodiments will be described. In the following explanations, portions equivalent to those of the above-explained embodiment are denoted by the same reference numerals and detailed explanations are omitted.

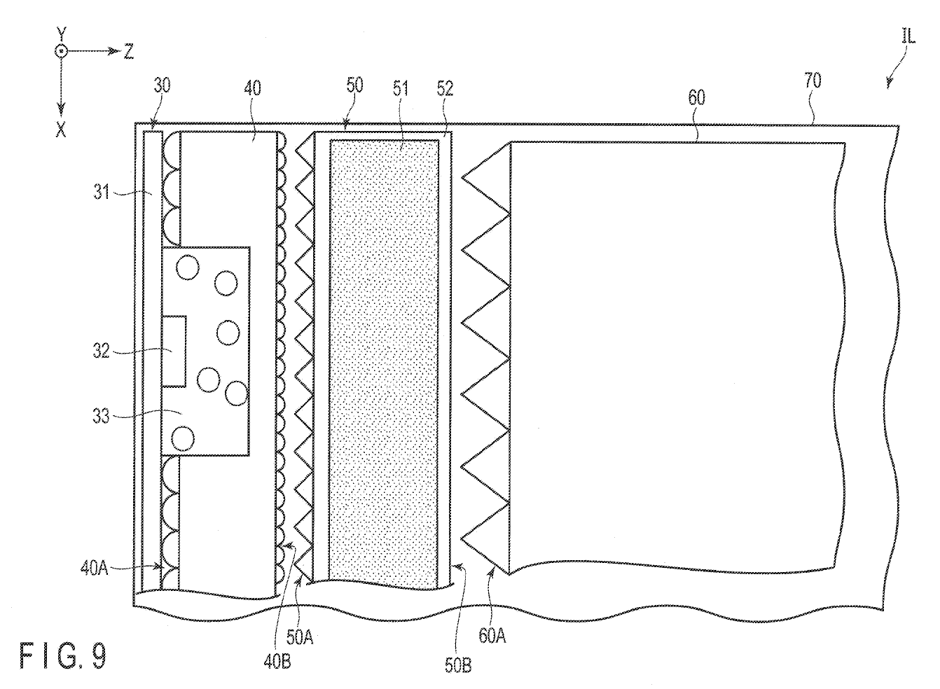

FIG. 9 is a plan view showing a configuration of an illumination device IL according to another embodiment.

The illumination device IL shown in FIG. 9 is different from the illumination device IL shown in FIG. 3 with respect to a feature that the end surfaces 40A and 40B of the sub-light guide 40, the end surface 50A of the wavelength converting member 50, and the end surface 60A of the main light guide 60 are uneven surfaces. The embodiment is not limited to the example illustrated, but at least one of the end surfaces 40A, 40B, 50A, and 60A may be an uneven surface.

In the example illustrated, each of the end surfaces 40A and 40B is formed of the lens array in which the lenses are arranged in the first direction X. Each of the lenses is, for example, a cylindrical lens including a generator extending in the second direction Y but may be a convex lens, a concave lens or the like having a spherical surface. Each of the end surfaces 50A and 60A is formed of the lens array in which the lenses are arranged in the first direction X. For example, each of the prisms extends in the second direction Y.

In this embodiment, too, the same advantages as those explained above can be obtained. In addition, since the end surface 40B is an uneven surface, the efficiency of emission of the light emitted from the sub-light guide 40 to the wavelength converting member 50 can be improved and the directivity of the light emitted from the sub-light guide 40 can also be improved.

In addition, since the end surface 50A is an uneven surface, the efficiency of incidence of the light incident from the sub-light guide 40 to the wavelength converting member 50 can be improved and the directivity of the light traveling to the emitting material 51 in the wavelength converting member 50 can also be controlled.

Since the end surface 60A is an uneven surface, the efficiency of incidence of the light incident from the wavelength converting member 50 to the main light guide 60 can be improved.

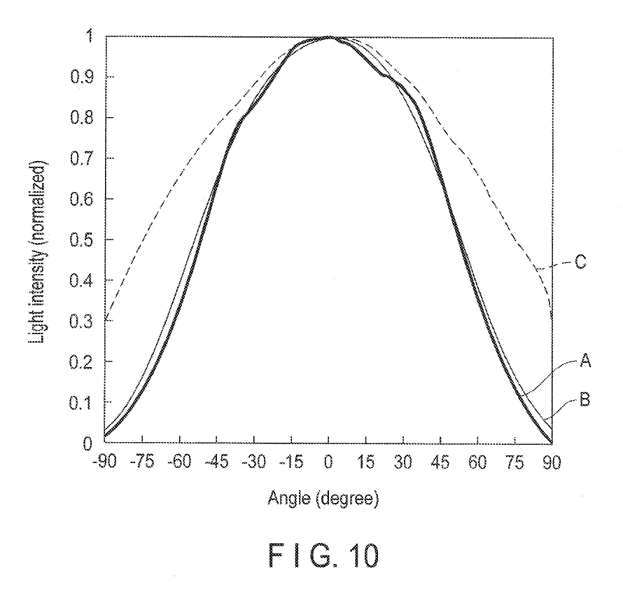

FIG. 10 is a graph for explanation of a directivity of a light beam emitted from the sub-light guide 40 of the illumination device IL shown in FIG. 9.

In the graph, a horizontal axis indicates a normal of the end surface 40B, i.e., an angle of inclination to the third direction Z, and a vertical axis indicates the light intensity. The light intensity is normalized such that its maximum value is 1. In the graph, thick line A indicates a profile of the emitted light using the angle of inclination along the first direction X as the lateral axis and narrow line B indicates a profile of the emitted light using the angle of inclination along the second direction Y as the lateral axis. Dotted line C in the graph indicates a profile of the emitted light of a light-emitting diode (referential example) in which the light emitting surface is surrounded by the package.

As illustrated in the graph, it can be confirmed that approximately equivalent directivity in the first direction X and the second direction Y can be obtained from the light emitted from the sub-light guide 40 and higher directivity than the emitted light of the referential example can be obtained from the light emitted from the sub-light guide 40, in the illumination device according to the present embodiment.

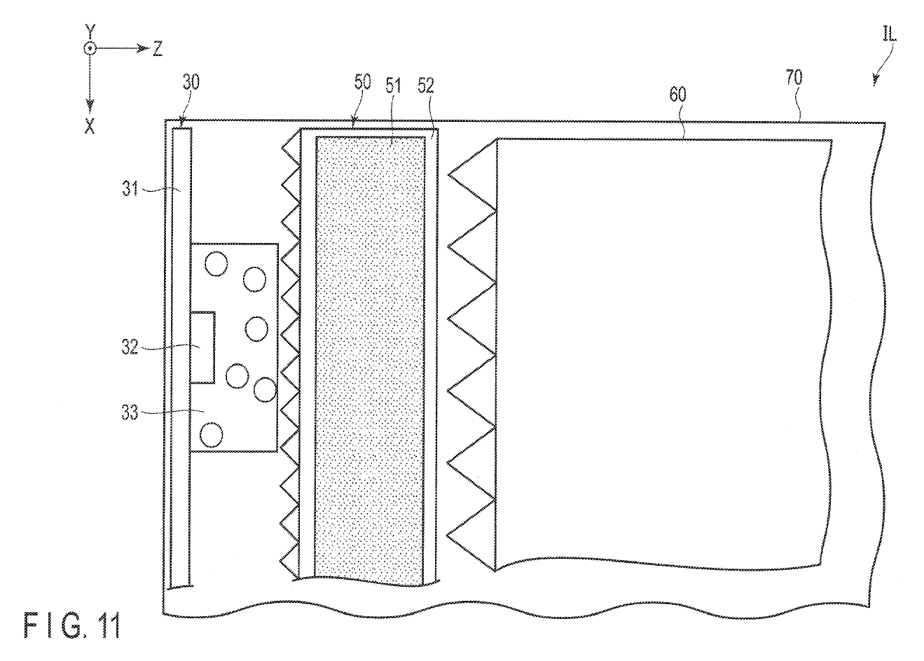

FIG. 11 is a plan view showing a configuration of an illumination device IL according to the other embodiment.

The illumination device IL shown in FIG. 11 is different from the illumination device IL shown in FIG. 3 with respect to a feature that the sub-light guide is not disposed. In addition, an air layer is located between the sealing members 33 and the wavelength converting member 50. In this embodiment, too, the same advantages as those explained above can be obtained.

According to the embodiments, as described above, the illumination device and the display device capable of improving the efficiency of use of light can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An illumination device comprising:
a light emitting chip including a main surface and a side surface and emitting light;
a sealing member including a scattering member and sealing the main surface and the side surface; and
a wavelength converting member converting a wavelength of the light emitted from the light emitting chip.

2. The illumination device of claim 1, further comprising:
a printed circuit board on which the light emitting chip is directly mounted,
wherein
the sealing member is in contact with a surface of the printed circuit board on which the light emitting chip is mounted.

3. The illumination device of claim 1, wherein
the sealing member is formed of a transparent resin in which the scattering member is dispersed.

4. The illumination device of claim 1, further comprising:
a sub-light guide which is located between the sealing member and the wavelength converting member and comprises a recess portion surrounding the sealing member.

5. The illumination device of claim 4, wherein
the sub-light guide has a first surface opposed to the wavelength converting member and the first surface is an uneven surface.

6. The illumination device of claim 1, wherein
the wavelength converting member includes a second surface on which the light emitted from the light emitting chip is made incident and the second surface is an uneven surface.

7. The illumination device of claim 1, further comprising:
a main light guide opposed to the wavelength converting member.

8. The illumination device of claim 7, wherein
the main light guide includes a third surface on which light emitted from the wavelength converting member is made incident and the third surface is an uneven surface.

9. The illumination device of claim 1, wherein
the wavelength converting member comprises an emitting material which absorbs the emitted light and emits light having a wavelength longer than the emitted light.

10. The illumination device of claim 9, wherein
the emitting material is formed of quantum dots.

11. A display device comprising:
an illumination device; and
a display panel illuminated by the illumination device,
the illumination device comprising:
a light emitting chip including a main surface and a side surface and emitting light;
a sealing member including a scattering member and sealing the main surface and the side surface; and
a wavelength converting member converting a wavelength of the light emitted from the light emitting chip.

12. The display device of claim 11, further comprising:
a printed circuit board on which the light emitting chip is directly mounted,
wherein
the sealing member is in contact with a surface of the printed circuit board on which the light emitting chip is mounted.

13. The display device of claim 11, wherein
the sealing member is formed of a transparent resin in which the scattering member is dispersed.

14. The display device of claim 11, further comprising:
a sub-light guide which is located between the sealing member and the wavelength converting member and comprises a recess portion surrounding the sealing member.

15. The display device of claim 14, wherein
the sub-light guide has a first surface opposed to the wavelength converting member and the first surface is an uneven surface.

16. The display device of claim 11, wherein
the wavelength converting member includes a second surface on which the light emitted from the light emitting chip is made incident and the second surface is an uneven surface.

17. The display device of claim 11, further comprising:
a main light guide opposed to the wavelength converting member.

18. The display device of claim 17, wherein
the main light guide includes a third surface on which light emitted from the wavelength converting member is made incident and the third surface is an uneven surface.

19. The display device of claim 11, wherein
the wavelength converting member comprises an emitting material which absorbs the emitted light and emits light having a wavelength longer than the emitted light.

20. The display device of claim 19, wherein
the emitting material is formed of quantum dots.
